(19) United States
(12) Patent Application Publication
(10) Pub. No.: US 2012/0183764 A1
(43) Pub. Date: Jul. 19, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/159,548

(22) Filed: Jun. 14, 2011

(30) Foreign Application Priority Data
Jan. 13, 2011 (CN) 201110006663.0

(51) Int. Cl. B32B 9/04; C09D 5/00; C23C 14/06; B32B 33/00; C23C 14/35

(52) U.S. Cl. 428/336; 428/457; 428/426; 204/298.13; 204/298.07; 106/287.27

(57) ABSTRACT

A coated article is described. The coated article includes a substrate, and an anti-fingerprint film formed on the substrate. The anti-fingerprint film is a carbon-nitrogen-fluorine layer. The carbon-nitrogen-fluorine has a chemical formula of C_{X}N_{1-X}F_{Y}, wherein 0.6≦X≦0.8 and 0.2≦Y≦0.4. A method for making the coated article is also described.

### BACKGROUND

1. Technical Field

The present disclosure relates to coated articles, particularly to a coated article having an anti-fingerprint property and a method for making the coated article.

2. Description of Related Art

Many electronic device housings are coated with anti-fingerprint film. The anti-fingerprint film is commonly painted on the housing as a paint containing organic anti-fingerprint substances. However, the printed film is thick (commonly 2 μm-4 μm) and not very effective. Furthermore, the printed film has a poor abrasion resistance, and may look oily. Additionally, the anti-fingerprint film may contain residual free formaldehyde, which is not environmentally friendly.

Therefore, there is room for improvement within the art.

### BRIEF DESCRIPTION OF THE FIGURES

Many aspects of the coated article can be better understood with reference to the following figures. The components in the figure are not necessarily drawn to scale, the emphasis instead being placed upon clearly illustrating the principles of the coated article. Moreover, in the drawings like reference numerals designate corresponding parts throughout the several views.

FIG. 1 is a cross-sectional view of an exemplary embodiment of a coated article.

FIG. 2 is an overlook view of an exemplary embodiment of a vacuum sputtering device.

### DETAILED DESCRIPTION

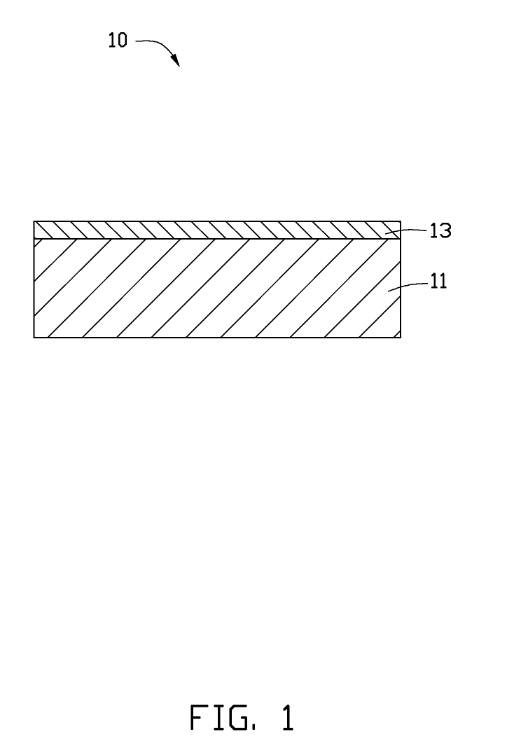

FIG. 1 shows a coated article 10 according to an exemplary embodiment. The coated article 10 includes a substrate 11, and an anti-fingerprint film 13 formed on a surface of the substrate 11.

The substrate 11 may be made of stainless steel or glass.

The anti-fingerprint film 13 is a nano-dimensioned carbon-nitrogen-fluorine layer. The carbon-nitrogen-fluorine has a chemical formula of C_{X}N_{1-X}F_{Y}, with 0.6≦X≦0.8, 0.2≦Y≦0.4.

The contact angle between the anti-fingerprint film 13 and water-oil droplet has been tested on the coated article 10. The contact angle is defined by an included angle between the surface of the anti-fingerprint film 13 and the tangent line of the water-oil droplet. The test indicates that the contact angle between the anti-fingerprint film 13 and the water-oil droplet is about 108°-111°. Thus, the anti-fingerprint film 13 has a good anti-fingerprint property.

The anti-fingerprint film 13 has a thickness of about 600 nm-900 nm, which is relatively thin. The anti-fingerprint film 13 may be formed by an environmentally friendly vacuum magnetron sputtering method. Comparison with the painted anti-fingerprint film shows that the anti-fingerprint film 13 is tightly bonded to the substrate 11, and provides the coated article 10 with a good abrasion resistance.

A method for making the coated article 10 may include the following steps:

The substrate 11 is pre-treated, Such pre-treating process may include the following steps:

The substrate 11 is cleaned in an ultrasonic cleaning device (not shown) which is filled with ethanol or acetone.

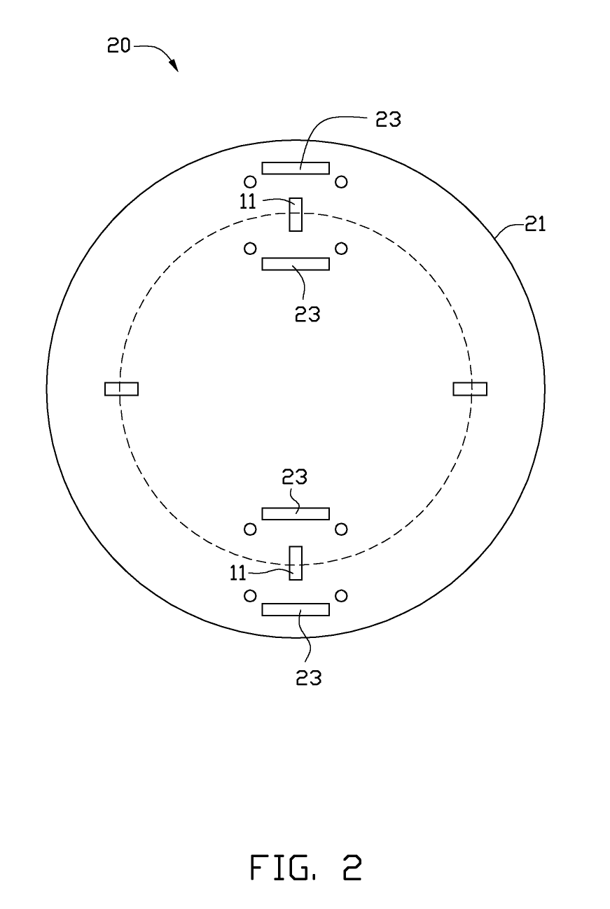

The substrate 11 is plasma cleaned. Referring to FIG. 2, the substrate 11 may be positioned in a coating chamber 21 of a vacuum sputtering device 20. The coating chamber 21 is fixed with graphite targets 23 therein. The coating chamber 21 is then evacuated to about 4.0×10⁻³ Pa. Argon gas having a purity of about 99.999% may be used as a working gas and is injected into the coating chamber 21 at a flow rate of about 500 standard-state cubic centimeters per minute (sccm). The substrate 11 may be biased with a negative bias voltage of about −400 V, then high-frequency voltage is produced in the coating chamber 21 and the argon gas is ionized to plasma. The plasma then strikes the surface of the substrate 11 to clean the surface of the substrate 11. Plasma cleaning the substrate 11 may take about 10 minutes (min). The plasma cleaning process enhances the bond between the substrate 11 and the anti-fingerprint film 13. The graphite targets 23 are unaffected by the pre-cleaning process.

The anti-fingerprint film 13 may be magnetron sputtered on the pretreated substrate 11 by using an intermediate frequency power for the graphite targets 23. Magnetron sputtering of the anti-fingerprint film 13 is implemented in the coating chamber 21. The inside of the coating chamber 21 is heated to about 60-180° C. Nitrogen (N₂) and carbon tetrafluoride (CF₄) may be used as reaction gases and injected into the coating chamber 21 at a flow rate of about 300 sccm-420 sccm and 15 sccm-70 sccm respectively. Argon gas may be used as a working gas and is injected into the coating chamber 21 at a flow rate of about 300 sccm-420 sccm. The intermediate frequency power is then applied to the graphite targets 23 fixed in the coating chamber 21, so the N₂ and the CF₄ are ionized and chemically react with carbon atoms which are sputtered off from the graphite targets 23 to deposit the anti-fingerprint film 13 on the substrate 11. The intermediate frequency power for the graphite targets 23 may be of 5 kilowatt (KW) −10 KW. During the depositing process, the substrate 11 may be biased with a negative bias voltage. The negative bias voltage may be about −50 V to about −150 V. The negative bias voltage may have a duty ratio of about 50%. Depositing of the anti-fingerprint film 13 may take about 20 min-60 min.

Specific examples of making the coated article 10 are described as following. The pre-treating process including the ultrasonic cleaning and the plasma cleaning in these specific examples may be substantially the same as described above so it is not described here again. Additionally, the process of magnetron sputtering the anti-fingerprint film 13 in the specific examples is substantially the same as described above, and the specific examples mainly emphasize the different process parameters of making the coated article 10.

### EXAMPLE 1

The substrate 11 is made of stainless steel.

Sputtering to form the anti-fingerprint film 13 having the chemical formula of C_{X}N_{1-X}F_{Y}: the flow rate of argon gas is 420 sccm, the flow rate of N₂ is 150 sccm, the flow rate of CF₄ is 15 sccm; the substrate 11 has a negative bias voltage of −50 V with a duty ratio of 50%; the graphite targets 23 are applied with an intermediate frequency power at a level of 6 KW; the temperature inside of the coating chamber 21 is 60° C.; sputtering of the anti-fingerprint film 13 takes 30 min.

The anti-fingerprint film 13 of example 1 has a thickness of 620 nm. The X and Y within the C_{X}N_{1-X}F_{Y} have a value of 0.62 and 0.28 respectively. The contact angle between the anti-fingerprint film 13 and water-oil droplet is 108°.

### EXAMPLE 2

Unlike the examples 1, the substrate 11 of example 2 is made of glass. Except the above difference, the remaining experiment conditions of example 2 are respectively the same as in example 1.

### EXAMPLE 3

The substrate 11 is made of stainless steel.

Sputtering to form the anti-fingerprint film 13 having the chemical formula of C_{X}N_{1-X}F_{Y}: the flow rate of argon gas is 300 sccm, the flow rate of N₂ is 220 sccm, the flow rate of CF₄ is 62 sccm; the substrate 11 has a negative bias voltage of −150 V with a duty ratio of 50%; the graphite targets 23 are applied with an intermediate frequency power at a level of 10 KW; the temperature inside of the coating chamber 21 is 150° C.; sputtering of the anti-fingerprint film 13 takes 45 min.

The anti-fingerprint film 13 of example 3 has a thickness of 860 nm. The X and Y within the C_{X}N_{1-X}F_{Y} have a value of 0.8 and 0.36 respectively. The contact angle between the anti-fingerprint film 13 and water-oil droplet is 111°.

### EXAMPLE 4

Unlike the examples 3, the substrate 11 of example 4 is made of glass. Except the above difference, the remaining experiment conditions of example 4 are respectively the same as in example 3.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
an anti-fingerprint film formed on the substrate, the anti-fingerprint film being a nano-dimensioned carbon-nitrogen-fluorine layer, the carbon-nitrogen-fluorine having a chemical formula of C_{X}N_{1-X}F_{Y}, with 0.6≦X≦0.8 and 0.2≦Y≦0.4.

2. The coated article as claimed in claim 1, wherein the anti-fingerprint film has a thickness of about 600 nm-900 nm.

3. The coated article as claimed in claim 1, wherein the anti-fingerprint film is formed by magnetron sputtering.

4. The coated article as claimed in claim 1, wherein the substrate is made of stainless steel or glass.

5. The coated article as claimed in claim 1, wherein the anti-fingerprint has a contact angle of about 108°-111° with water-oil droplets.

6. A method for making a coated article, comprising:
providing a substrate; and
forming an anti-fingerprint film on the substrate by magnetron sputtering, using nitrogen, carbon tetrafluoride as reaction gases and using graphite targets; the anti-fingerprint film being a nano-dimensioned carbon-nitrogen-fluorine layer, the carbon-nitrogen-fluorine having a chemical formula of C_{X}N_{1-X}F_{Y} with 0.6≦X≦0.8 and 0.2≦Y≦0.4.

7. The method as claimed in claim 6, wherein the nitrogen has a flow rate of about 300 sccm-420 sccm, the carbon tetrafluoride has a flow rate of about 15 sccm-70 sccm; the graphite targets are applied with an intermediate frequency power of 5 KW-10 KW; magnetron sputtering of the anti-fingerprint film uses argon as a working gas, the argon has a flow rate of about 300 sccm-420 sccm; magnetron sputtering of the anti-fingerprint film is conducted at a temperature of about 60° C.-180° C., vacuum sputtering of the anti-fingerprint film takes about 20 min-60 min.

8. The method as claimed in claim 7, wherein the substrate is biased with a negative bias voltage of about −50V to about −150V with a duty ratio of about 50% during magnetron sputtering of the anti-fingerprint film.

9. The method as claimed in claim 6, further comprising a step of pre-treating the substrate before forming the anti-fingerprint film.

10. The method as claimed in claim 9, wherein the pre-treating process comprises ultrasonic cleaning the substrate and plasma cleaning the substrate.

11. The method as claimed in claim 10, wherein plasma cleaning the substrate uses argon as a working gas, the argon has a flow rate of about 500 sccm; the substrate is biased with a negative bias voltage of −400V; plasma cleaning of the substrate takes about 10 min.

12. The method as claimed in claim 6, wherein the substrate is made of stainless steel or glass.

13. The method as claimed in claim 6, wherein the anti-fingerprint film has a thickness of about 600 nm-900 nm.

14. The method as claimed in claim 6, wherein the anti-fingerprint has a contact angle of about 108°-111° with water-oil droplets.
